(19) United States
(12) Patent Application Publication
(10) Pub. No.: US 2013/0003248 A1
(43) Pub. Date: Jan. 3, 2013

(54) SUBSTRATE LIFTING METHOD AND SUBSTRATE LIFTING DEVICE

(75) Inventors: Frank WEGERT, Holzweissig (DE); Torsten HÄNßGEN, Dessau (DE)

(73) Assignee: Q-CELLS SE, Bitterfeld-Wolfen / OT Thalheim (DE)

(21) Appl. No.: 13/468,538

(22) Filed: May 10, 2012

(30) Foreign Application Priority Data
May 12, 2011 (DE) 102011050322.6

(51) Int. Cl. H02N 13/00

(52) U.S. Cl. 361/234

(57) ABSTRACT

A method for picking up a substrate includes leading an electrostatic holder to the substrate, applying an electrical voltage having a first voltage value to the electrostatic holder in such a way that the substrate is accelerated in the direction of the electrostatic holder, and reducing the voltage applied to the electrostatic holder to a second voltage value, the absolute value of which is lower than the first voltage value.

### CROSS REFERENCE TO RELATED APPLICATIONS

This application claims priority to German Application No. 10 2011 050 322.6 filed on May 12, 2011, the entire disclosures of which are incorporated herein by reference.

### FIELD OF THE INVENTION

The invention relates to a method for picking up a substrate, and to a substrate pick-up device which carries out this method.

### BACKGROUND

In order to hold substrates during their processing and to transport them from one processing installation to another, gripping and holding devices that work rapidly and efficiently, but at the same time gently, are required. In solar cell production, in particular, compressed air and vacuum gripping systems are used. The latter generate a vacuum between the substrate and a holding surface of the gripping system, such that the substrate is pressed against the holding surface. By contrast, gripping and holding devices operated by compressed air are based on the so-called Venturi effect. In this case, a reduced pressure is generated on account of a gas flow between the substrate and the holding surface, and likewise leads to the substrate being fixed to the holding surface.

Such systems using compressed air or vacuum often have the disadvantage that the substrates warp on account of non-uniform force transmission. Not only can this warpage lead to non-uniform and unforeseeable processing results, but at the same time it increases the probability of the substrates being damaged, particularly if the latter are very thin. The use of vacuum systems additionally entails the risk, in the case of splintering on the substrate, that substrate fragments will be sucked in and detrimentally affect the vacuum system.

An alternative to such compressed air or vacuum holding systems is holding devices that use electrostatic forces to press the substrate onto the holding surface. Such electrostatic chucks are disclosed, for example, in US2010277850A and US2004016405A. They have metallic electrodes on their holding surfaces, a constant voltage being applied to said electrodes. On account of the applied voltage, electrical charges are displaced in the substrate and the substrate surface is thereby polarized. As a result, electrostatic holding forces are generated between the substrate surface and the holding surface. In US2010277850A, the chuck even has a plurality of holding regions, in each of which the holding voltage and thus the electrostatic holding force can be set differently in order to hold the substrate as flat as possible and to avoid warpage or mechanical stresses.

However, conventional electrostatic holders have the disadvantage that they are only suitable for fixedly holding substrates. The abovementioned known electrostatic chucks, too, firstly have to be loaded with the substrate, which is generally done by means of a robot arm that picks up the substrate and deposits it on the chuck. Afterwards, the constant voltage is switched on and the substrate is pressed with constant force onto the chuck. For gripping the substrate, the robot arm in turn uses one of the gripping and holding mechanisms explained in the introduction.

If it were desired to grip and raise the substrate by means of an electrostatic holder, then either the holder would have to be led to the substrate with voltage switched on, which could lead to damage to the substrate on account of the high electrostatic attractive force, or the holder would have to come into contact with the substrate while it is arranged on a support. In this case, too, the substrate can be damaged by being squashed between the support and the holder.

Therefore, it is an object of the invention to provide a method and a device for a gentle and secure substrate pick-up for holding and transporting substrates.

### SUMMARY OF THE INVENTION

The object is achieved according to the invention by means of a substrate pick-up method comprising the features of claim 1 and a substrate pick-up device comprising the features of claim 13. Advantageous developments of the invention are presented in the dependent claims.

The invention is based on the concept of using the principle of electrostatic holders or electrostatic chucks also when gripping and raising a substrate. For this purpose, the electrostatic holder is not brought directly into contact with the substrate before the electrical voltage is actually switched on, rather the electrostatic holder is firstly only led to the substrate. When the holder has been led sufficiently close to the substrate, for example to a distance of a few millimetres or closer, the electrical voltage is applied to the electrostatic holder, that is to say to electrodes of the electrostatic holder. The applied voltage firstly has a first voltage value, which has to be high enough to exert a sufficiently high attractive force on the substrate and to accelerate the latter in the direction of the electrostatic holder.

In order that the substrate does not impact against the holder at high speed, the voltage applied to the electrostatic holder is set at a later point in time to a second voltage value, which is lower than the first voltage value, preferably lower by at least 20%, 30% or 40%. The period of time between applying the first voltage and applying the second voltage is preferably a few microseconds up to about 10 μs, 15 μs or 20 μs. The changing of the applied voltage is controlled by a control device. The lower second voltage value should be chosen such that the acceleration of the substrate in the direction of the holder decreases, such that contact is made between substrate and holder gently and with as little impact energy as possible. The applied voltage can then be maintained or reduced to an even lower voltage value. The holder together with the substrate can subsequently be moved by means of a transport device.

The substrates are preferably semiconductor wafers, in particular solar cell wafers. By means of the substrate pick-up method explained here, even wafers having a very small substrate thickness, for example less than 200 μm, 150 μm, 100 μm or 80 μm, can be picked up and transported with a low risk of braking Since, particularly in the field of photovoltaics, the substrate thickness is constantly being reduced in order to lower costs, gentle pick-up and holding methods are increasingly gaining in importance here. By means of the electrostatic holder, the substrate can additionally be held securely during processing methods in which a force is exerted on the substrate, for example during printing processes.

In simple embodiments, the electrostatic holder comprises two electrodes, that is to say one pair of electrodes, to which the voltage can be applied. In one preferred embodiment, however, provision is made for a multipolar electrostatic holder having two, three or more pairs of electrodes to be led to the substrate. In this case, each pair of electrodes can define a holding region at which a holding force can be set individually by means of a suitable choice of the voltage applied thereto.

In the simplest implementation of the method, the voltage applied to the holder can be reduced substantially abruptly from the first to the second voltage values. In one advantageous development, by contrast, provision is made for the voltage applied to the electrostatic holder to be reduced from the first voltage value to the second voltage value via one or more intermediate voltage values.

Expediently, provision can even be made for the voltage applied to the electrostatic holder to be reduced from the first voltage value to the second voltage value continuously. It is thereby possible to achieve a gradual reduction in the acceleration of the substrate in the direction of the holder, such that the substrate comes to bear against the holder as softly as possible.

It is preferably provided that a distance between the electrostatic holder and the substrate is determined. For this purpose, the substrate pick-up device expediently has a distance determining device for determining a distance between the electrostatic holder and the substrate.

The distance can be determined, for example, by means of an optical distance measurement. Advantageously, however, provision can be made for the distance between the electrostatic holder and the substrate to be determined on the basis of a capacitance determination. This can be done by means of one or more additional electrodes arranged on the holder for the purpose of capacitive distance determination. Without an additional modification, however, the capacitance determination can also be carried out by means of the electrodes of the electrostatic holder to which the electrical holding voltage is applied. This is because the capacitance formed by said electrodes also changes depending on the distance between the electrostatic holder and the substrate.

One advantageous configuration provides for the voltage applied to the electrostatic holder to be controlled depending on the distance determined between the electrostatic holder and the substrate. In particular, the reduction of the voltage applied to the electrostatic holder from the first voltage value to the second voltage value can be triggered if the distance determined between the electrostatic holder and the substrate falls below a minimum distance.

In this case, however, it is not absolutely necessary for the distance between the electrostatic holder and the substrate to be continuously measured. Instead, by way of example, the undershooting of the minimum distance can be determined by means of a light barrier. Moreover, in the case of the distance determination it is not necessary for the distance to be calculated in a specific unit of measurement. Rather, it suffices if a distance-determining variable is used for controlling the applied voltage, for example a capacitance value determined during the capacitance determination or a light intensity measured during an optical distance measurement.

Instead of control of the applied voltage depending on the distance between the electrostatic holder and the substrate, provision can advantageously be made for the voltage applied to the electrostatic holder to be reduced from the first voltage value to the second voltage value after a predetermined period of time. Such a voltage change can also be effected substantially abruptly, if appropriate via intermediate voltage values, or continuously. Particularly in the case of a sudden change, that is to say if in an idealized manner there are only two voltage values, the voltage change after a predetermined period of time means that the period of time starts from the point in time when the first voltage value is applied. Suitable parameters, for example a suitable period of time or a suitable continuous voltage profile, for such voltage control not determined by the distance between substrate and holder can be determined and stored beforehand on the basis of calibration experiments for different substrates.

In accordance with one preferred configuration, provision is made for the substrate to be accelerated in the direction of the electrostatic holder counter to gravitational force. To put it another way, the electrostatic holder is situated above the substrate and the substrate has to overcome a height difference with respect to the holder during the pick-up method. The substrate can subsequently be transported further by means of the holder perpendicularly or parallel to the gravitational force. For acceleration counter to gravitational force, the first voltage value has to be sufficiently high in order that the electrostatic attractive force that is formed exceeds the gravitational force of the substrate.

It is preferably provided that the substrate is held on the electrostatic holder by means of a holding voltage applied thereto. Said holding voltage can in this case be equal to the second voltage value, or higher or lower.

After the substrate has been picked up by means of the electrostatic holder, it can be held by the latter for the course of a treatment, for example a surface processing. In one expedient development of the method, provision is alternatively or additionally made for the substrate held on the electrostatic holder to be transported to a depositing location, to be released from the electrostatic holder by means of the reduction of the electrical voltage applied to the electrostatic holder, and to be deposited at the depositing location.

### BRIEF DESCRIPTION OF THE DRAWINGS:

The invention is explained below on the basis of exemplary embodiments with reference to the figures, in which:

FIGS. 1a, b, c show different stages in the process of picking up a substrate by means of an electrostatic holder; and

FIG. 2 shows a possible voltage profile for the voltage applied to the electrostatic holder when picking up the substrate.

### DETAILED DESCRIPTION:

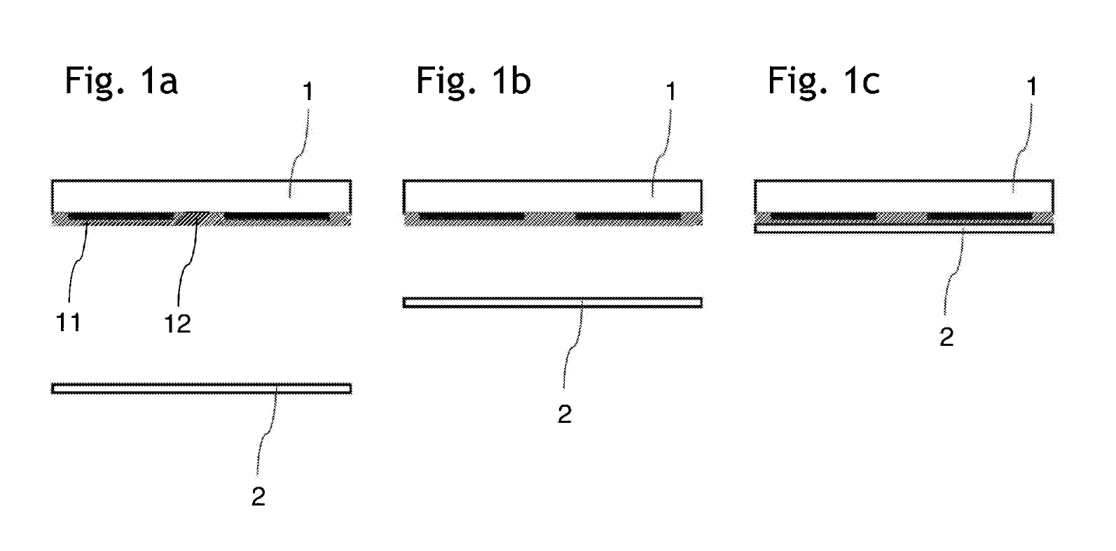

The picking-up of a substrate 2 by means of an electrostatic holder 2 in accordance with one preferred embodiment is illustrated with reference to FIGS. 1a, 1b and 1c. In this case, FIGS. 1a, 1b and 1c each show a schematic cross-sectional view of the arrangement of the substrate 2 with respect to the holder 1 in different pick-up states. The substrate 2 is, for example, a semiconductor wafer for solar cell production.

As illustrated in FIG. 1a, the electrostatic holder 1 in this case has two electrodes 11, between which an electrical voltage is applied. The electrodes 11 are covered by an electrical insulation 12 in order to avoid a short circuit upon touching the substrate 2. In FIG. 1a, the electrostatic holder 1 is led sufficiently close to the substrate 2, such that the substrate 2, on account of the applied voltage, begins to be accelerated in the direction of the holder 1. The distances between substrate 2 and holder 1 in FIGS. 1a and 1b are not illustrated to scale, since the distance between the holder 1 and the substrate 2 at which the substrate 2 is accelerated counter to gravitational force is much smaller in comparison with the dimensions of the holder 1 and the substrate 2.

On account of the acceleration, the distance between the holder 1 and the substrate 2 decreases, which is illustrated in FIG. 1b. At this point, the voltage applied to the electrodes 11 should already be reduced in order to reduce the acceleration of the substrate 2 in the direction of the holder 1 until, finally, as illustrated in FIG. 1c, the substrate 2 comes into contact with the electrostatic holder 1. To put it more precisely: with the insulation 12 of the holder 1. Starting from this point in time, the substrate 2 is fixedly held by the electrostatic holder 1 until the applied voltage is reduced to an extent such that the holding force exerted on account of the applied voltage can no longer compensate for gravitational force.

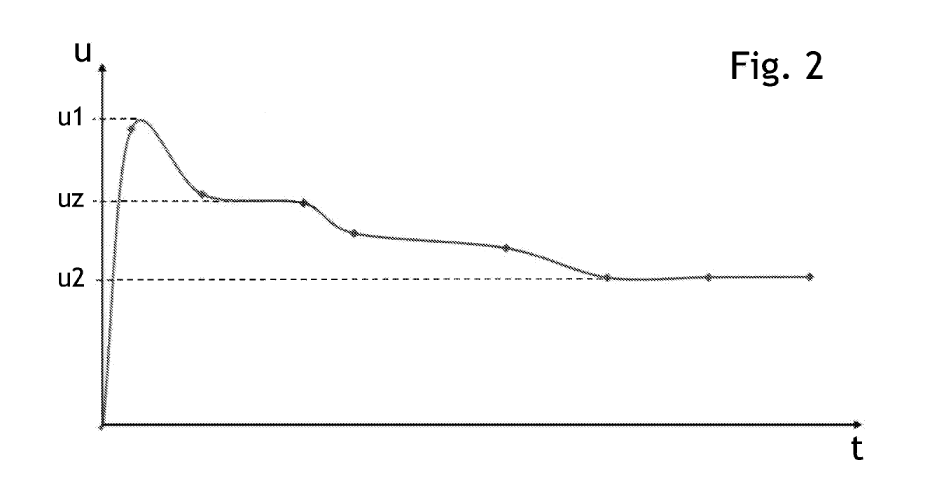

A preferred temporal profile of the applied voltage u is illustrated in FIG. 2. After the electrostatic holder 1 has been led close enough to the substrate 2, the applied voltage u is increased to the first voltage value u1. This gives rise to an electrostatic force that accelerates the substrate 2 in the direction of the holder 1. The voltage u is subsequently regulated to a lower intermediate voltage value uz in order to reduce the acceleration of the substrate 2. If the substrate 2 has reached the holder 1, the voltage is reduced to an even lower second voltage value u2.

The voltage values u1, uz and u2 depicted in FIG. 2 thus correspond to the applied voltage values in the positions illustrated in FIGS. 1a, 1b and 1c, respectively. The temporal separation between the curve positions depicted by points along the horizontal time axis in FIG. 2 is preferably in the range of from a few microseconds to about 10 μs.

The voltage curve illustrated in FIG. 2 or some other voltage curve can be stored in a control device of the substrate pick-up device comprising the electrostatic holder 1, in order to be retrieved during the substrate pick-up method. By way of example, it is also possible to store a plurality of such voltage curves in each case for different substrates. Alternatively, however, the applied voltage can also be controlled in a manner dependent on a parameter which changes with the distance between the substrate 1 and the electrostatic holder 1 and is determined continuously. Also possible is an embodiment in which the last-mentioned active, that is to say distance-dependent, control is used for calibration purposes and in this case a voltage curve determined in this way is measured and stored in order to be able to have recourse thereto during later pick-up methods.

1. A method for picking up a substrate, comprising:
leading an electrostatic holder to the substrate;
applying an electrical voltage having a first voltage value to the electrostatic holder in such a way that the substrate is accelerated in the direction of the electrostatic holder; and
reducing the voltage applied to the electrostatic holder to a second voltage value, the absolute value of which is lower than the first voltage value.

2. The method according to claim 1, wherein said multipolar electrostatic holder is led to the substrate.

3. The method according to claim 1, wherein the voltage applied to the electrostatic holder is reduced from the first voltage value to the second voltage value via intermediate voltage values.

4. The method according to claim 3, wherein the voltage applied to the electrostatic holder is reduced from the first voltage value to the second voltage value continuously.

5. The method according to claim 1, wherein a distance between the electrostatic holder and the substrate is determined.

6. The method according to claim 5, wherein the distance between the electrostatic holder and the substrate is determined on the basis of a capacitance determination.

7. The method according to claim 5, wherein the voltage applied to the electrostatic holder is controlled in a manner dependent on the distance determined between the electrostatic holder and the substrate.

8. The method according to claim 7, wherein the reduction of the voltage applied to the electrostatic holder from the first voltage value to the second voltage value is triggered if the distance determined between the electrostatic holder and the substrate falls below a minimum distance.

9. The method according to claim 1, wherein the voltage applied to the electrostatic holder is reduced from the first voltage value to the second voltage value after a predetermined period of time.

10. The method according to claim 1, wherein the substrate is accelerated in the direction of the electrostatic holder counter to gravitational force.

11. The method according to claim 1, wherein the substrate is held on the electrostatic holder by means of a holding voltage applied thereto.

12. The method according to claim 1, wherein the substrate held on the electrostatic holder is transported to a depositing location, is released from the electrostatic holder by means of the reduction of the electrical voltage applied to the electrostatic holder and is deposited at the depositing location.

13. A substrate pick-up device, comprising:
an electrostatic holder having at least one electrode;
a transport device for the translation of the electrostatic holder;
a controllable voltage source electrically connected to the electrode;
a control device designed to lead the electrostatic holder to a substrate by means of the transport device, to apply an electrical voltage (u) having a first voltage value to the electrode of the electrostatic holder by means of the voltage source in such a way that the substrate is accelerated in the direction of the electrostatic holder, and to reduce the voltage applied to the electrode of the electrostatic holder to a second voltage value, the absolute value of which is lower than the first voltage value.

14. The substrate pick-up device according to claim 13, further comprising a distance determining device for determining a distance between the electrostatic holder and a substrate.

15. The method according to claim 2, wherein the voltage applied to the electrostatic holder is reduced from the first voltage value to the second voltage value via intermediate voltage values.

16. The method according to claim 6, wherein the voltage applied to the electrostatic holder is controlled in a manner dependent on the distance determined between the electrostatic holder and the substrate.
